(19) United States
(12) Patent Application Publication
(10) Pub. No.: US 2004/0150383 A1
(43) Pub. Date: Aug. 5, 2004

(54) Electrical component measuring instrument

(76) Inventor: Marcel Blais, Masson-Angers (CA)

Correspondence Address: BORDEN LADNER GERVAIS LLP, WORLD EXCHANGE PLAZA, 100 QUEEN STREET SUITE 1100, OTTAWA, ON, K1P 1J9, CA

(21) Appl. No.: 10/478,495

(22) PCT Filed: May 21, 2002
(86) PCT No.: PCT/CA02/00726

(30) Foreign Application Priority Data
May 22, 2001 (CA) 2,348,799

(51) Int. Cl. G01R 1/00

(52) U.S. Cl. 324/73.1

(57) ABSTRACT

The present invention provides a method and system for generating a distinct signature of electronic components that is compared to a known signature for identification and verification of the electronic component. The component signature is displayed on an alpha-numeric display for viewing by the user, or can be used as a pointer in a look-up table for displaying a string of text corresponding to the signature. In a digital generation method, a test sequence is executed, wherein a predetermined combination of logic levels are applied to the pins of a component. The logic levels applied to each pin are then compared to their respective feed-back logic levels. The sum of all the differences between the feed-back logic levels and the applied logic levels at the end of the test sequence is used in generating a signature. In an analog generation method, values calculated as a function of the waveform response of the component are used to generate a signature for the component.

### FIELD OF THE INVENTION

The present invention relates generally to electronic component testers.

### BACKGROUND OF THE INVENTION

Technicians and engineers frequently use digital multimeters and oscilloscopes to test and verify electronic components of an electronic product when the electronic product ceases to function partially or completely. Examples of electronic products include standard consumer electronics such as radios and televisions.

Verification of non-functioning products typically requires that the technician determine which of its constituent components no longer functions. This task can be challenging and time consuming even for a trained technician. The technician must first identify and understand the specific component they are testing in order to properly interpret the results of the test, because different components will have different criteria for testing for failure.

The verification and testing of electronic components is not limited to specially trained technicians and engineers. In the case of electronic components are found in automobiles, the task of verifying the functionality of an electronic component would lie upon the auto mechanic because it is neither cost effective to train auto mechanics in the art of electronics, nor is it cost effective to staff a full-time electronics technician. This type of problem will occur in any situation where people lacking skill in the art of electronics require some electronics knowledge to sufficiently perform their verification duties. Hence there exists a huge complexity involved in testing and verifying components by persons with less skill than trained technicians, resulting in longer testing times and even possible mis-identification of good components as failed components.

Existing multimeters have significant limitations that render them less practical to use. Most can only identify one or two components for each function, such as NPN or PNP transistors for example. But because there are virtually hundreds of different types of components, such a multimeter provides little value to the non-technical occasional user.

Users must understand and identify the function of each pin of an electronic component if a proper test is to be conducted with a multimeter. Testing can be especially time consuming when the user resorts to “trial and error” to determine if they have properly connected the multimeter probes.

Current multimeters cannot measure the maximum operating frequency of electronic components. Such a test can be used to verify that the component operates according to the manufacturer's specifications. This is an important test because the electronic component may function properly for a specific range of operating frequencies, but will fail to function properly beyond that specific frequency range.

Testing a group of interconnected components is not possible with a multimeter, because the connection of multiple components to a single node renders the multimeter measurement meaningless due to the multimeter's lack of interpretation of differences in current, voltage and impedance.

It follows that current multimeters can be difficult or complex to use, not only because of their aforementioned limitations, but because they require the user to understand its various modes and functions in order to properly test a specific component.

Furthermore the information displayed on the multimeter does not directly indicate to the user the functionality of the component, more precisely whether or not the device works. Instead, the information displayed requires an interpretation and application of technical knowledge, which the user often lacks, to determine if the component is good or not. Therefore an unskilled user can make false conclusions regarding the functionality of the tested component.

It is, therefore, desirable to provide a user-friendly measuring tool that quickly and accurately identifies the functionality of all electronic components.

### SUMMARY OF THE INVENTION

It is an object of the present invention to obviate or mitigate at least one disadvantage of the prior art. In particular, it is an object of the invention to provide a user friendly measuring instrument that identifies and verifies electrical components by assigning its own signature to the electrical component.

In a first aspect, the present invention provides an electrical component measuring instrument for generating a signature corresponding to the electrical component, the measuring instrument having probes for connecting to pins of an electrical component, a display for presenting characters, and a clock. The measuring instrument includes a test sequence generator, receiving a clock signal for generating a test sequence of test signals, probe drivers for receiving the test signals and applying current and voltage to the probes, and a data processing unit for receiving data corresponding to feedback current and voltage from each of the probes. The data processing unit executes functions upon the data to generate a code that is provided to the display. In an alternate embodiment of the present aspect, the frequency of the clock signal is variable.

In alternate embodiments of the present aspect, the measuring instrument includes a look-up table for displaying additional text corresponding to the code, and the probe drivers each include an inverter circuit. In further alternate embodiments, the probe drivers each include at least two tri-state inverter circuits connected in parallel or a D/A converter for providing a variable current to an inverter circuit.

In yet another embodiment of the present aspect, the data include logic signals corresponding to the feedback current and voltage, and a sense circuit receives the feedback current and voltage for generating the logic signals, where the sense circuit receives a reference voltage from a reference voltage generator. In another embodiment of the present aspect, the sense circuit includes a comparator or an A/D converter with a sample and hold circuit.

In another embodiment of the present aspect, the test sequence generator includes a counter circuit for providing the test signals, and the data processing unit includes logic circuitry for comparing the logic signals to the test signals and probe counters for counting the difference in number of the logic signals and the test signals in the test sequence. The probe counters then provide the code corresponding to the value of the probe counters. In yet a further embodiment of the present aspect, the logic circuitry includes XOR logic for determining the difference.

In a second aspect, the present invention provides an electrical component measuring instrument, for generating a signature corresponding to the electrical component, where the measuring instrument includes at least one probe for connection to pins of an electrical component and a display for presenting a character corresponding to the at least one probe. The measuring instrument includes a counter for generating an output logic signal, a probe driver for receiving the output logic signal and driving the at least one probe according to the state of the output logic signal, a sense circuit for receiving voltage feedback from the at least one probe and generating an input logic signal, logic circuitry for comparing the output logic signal to the input logic signal, and a probe counter having a probe counter value that is incremented when the output logic signal and the input logic signal differ. The display displays the character corresponding to the incremented probe counter value.

In an alternate embodiment of the present aspect, the at least one probe driver includes an inverter circuit, the sense circuit includes a comparator and a reference voltage circuit and the logic circuitry includes XOR logic.

In a third aspect, the present invention provides a method for generating a signature for an electrical component. The method includes the steps of driving probes connected to the electrical component in each iteration of a test sequence, collecting feedback data from the probes in each iteration, computing a code corresponding to the feedback data, and displaying the signature corresponding to the code.

In an alternate embodiment of the present aspect, the step of driving includes driving the probes with different current and voltage levels, and the step of collecting includes converting the feedback data into logic levels. In a further embodiment of the present aspect, the step of computing includes comparing the logic levels driven by the probes with the logic levels of the feedback data during each iteration of the test sequence, and counting the number of differences between the logic levels driven by the probes and the logic levels of the feedback data.

In yet another alternate embodiment of the present aspect, the probes are driven with a first waveform and the collected feedback data from all iterations of the test sequence forms a second waveform, and the step of computing includes calculating the absolute surface area (S) of the waveform, calculating the length of the absolute surface area (L) of the waveform, and calculating the distribution of the absolute surface area (D) of the waveform, where the code corresponding to the values of S, L and D.

In a fourth aspect, the present invention provides a method of generating a signature for an electrical system in operation including the steps of sampling a waveform of the electrical system, calculating the absolute surface area (S) of the waveform, calculating the length of the absolute surface area (L) of the waveform, calculating the distribution of the absolute surface area (D) of the waveform, and displaying the signature corresponding to the values of S, L and D.

In a fifth aspect, the present provides a probe for use with an electrical component measuring instrument. The probe includes an input node, a non-linear circuit coupled in series to the input node, and an output node coupled in series to the non-linear circuit.

In an alternate embodiment of the present aspect, the non-linear circuit includes serially connected pairs of parallel connected resistors and diodes, where value of each resistor is different.

Other aspects and features of the present invention will become apparent to those ordinarily skilled in the art upon review of the following description of specific embodiments of the invention in conjunction with the accompanying figures.

### BRIEF DESCRIPTION OF THE DRAWINGS

Embodiments of the present invention will now be described, by way of example only, with reference to the attached Figures, wherein:

FIG. 1 shows an electrical component measuring system according to an embodiment of the present invention;

FIG. 2 is a block diagram of the electrical component measuring instrument shown in FIG. 1;

FIG. 3 is a flow chart illustrating a method of generating a signature for an electronic component according to an embodiment of the present invention;

FIG. 4 is a flow chart illustrating the method of digital generation of a signature for an electronic component according to an embodiment of the present invention;

FIG. 5 is a circuit schematic of an electrical component measuring instrument according to an embodiment of the present invention;

FIG. 6 is a circuit schematic of a probe driver used in FIG. 5;

FIG. 7 is a circuit schematic of a digital tri-state probe driver;

FIG. 8 is a circuit schematic of an analog probe driver;

FIG. 9 is a graph illustrating the waveform response of a component;

FIG. 10 is a graph illustrating the parameter S(t).

FIG. 11 is a graph illustrating the mapping of parameters S, L, and D to a signature;

FIG. 12 is flow chart illustrating the method of analog generation of a signature for an electronic component according to an embodiment of the present invention;

FIG. 13 is an illustration of a probe of FIG. 1;

FIG. 14 is a circuit schematic of the probe of FIG. 13; and,

FIG. 15 is a graph illustrating the voltage-current characteristics of the circuit shown in FIG. 14.

### DETAILED DESCRIPTION

Generally, the present invention provides a method and system for generating a distinct signature of electronic components that is compared to a known signature for identification and verification of the electronic component. The component signature is displayed on an alpha-numeric display for viewing by the user, or can be used as a pointer in a look-up table for displaying a string of text corresponding to the signature. In a digital generation method, a test sequence is executed, wherein a predetermined combination of logic levels are applied to the pins of a component. The logic levels applied to each pin are then compared to their respective feed-back logic levels. The sum of all the differences between the feed-back logic levels and the applied logic levels at the end of the test sequence is used in generating a signature. In an analog generation method, values calculated as a function of the waveform response of the component are used to generate a signature for the component.

In general, component signatures are generated based on the electrical behaviour of the component in response to signals applied to the component's pins during a predefined test. A code corresponding to the behaviour of the pins is generated, converted into text, and both the code and the text can be displayed for the user to view.

In preferred embodiments of the present invention, the method and system for generating component signatures can be integrated with existing multimeters to complement their existing functions, or can be manufactured as a portable measuring instrument dedicated to generating component signatures. The measuring instrument can be assisted by a computer to perform additional tests to generate additional component signatures.

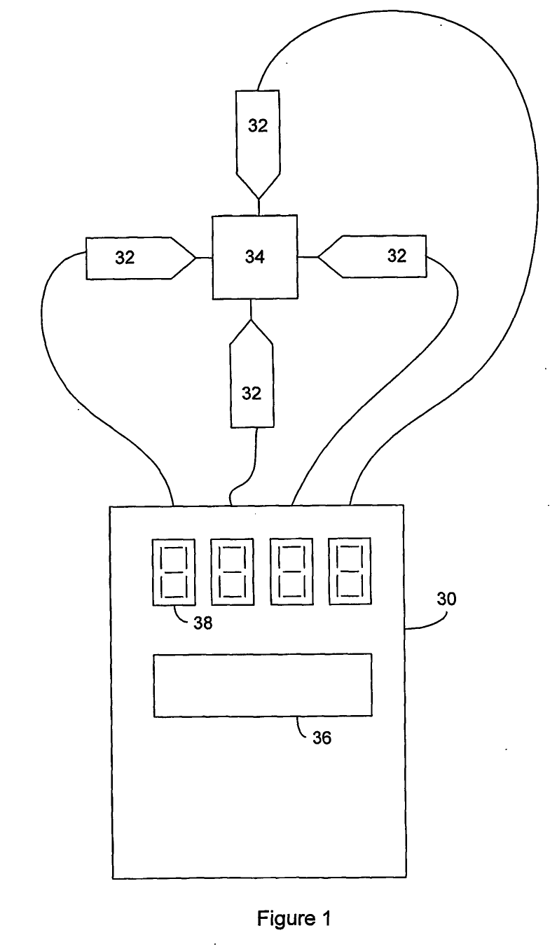

FIG. 1 illustrates an electronic component measuring system according to an embodiment of the present invention. The advantage of the measuring system shown in FIG. 1 is the portability, simplicity and ease of use of the device. The measuring system of FIG. 1 includes a measuring instrument 30 and four probes 32 connected to the measuring instrument 30. Measuring instrument 30 includes four LED displays 38 and a text display 36, which together form an alpha-numeric display such as a standard LCD. Although seven segment LED displays 38 are shown by example, any LED display can be used. Although not shown, those of skill in the art will understand that measuring instrument 30 can be driven by an external power source or by internal batteries. To test an electrical component 34, the four probes 32 are first connected to four pins of the electrical component 34. Then the user simply activates a switch (not shown) to initiate the test. Within 1 millisecond, the LED displays 38 will provide a numeric signature for the component 34. In the present embodiment, each probe 32 is associated with one of the LED displays 38. For example, if component 34 is a bridge rectifier, then the displayed signature can be <6331>.

If the user knows that component 34 is a functioning component, such as a new component, then the signature can be recorded as a reference for testing similar components by the same manufacturer, or even by other manufacturers. To test a potentially non-functioning bridge rectifier, the user simply connects the probes and initiates the test. If the displayed signature is <63,31>, then the device functions properly. If, however, the displayed signature is <5331>, then the bridge rectifier does not function properly. In an alternative embodiment of the present invention, the displayed signature can prompt the text display 36 to indicate the specific problem of the bridge rectifier.

It should be noted that a different signature will appear if the probes are connected to different pins of the same device. For example, the signature <3316> and <3613> are equivalent signatures of a functioning bridge rectifier. As long as the same digits appear in the signature of subsequently tested components, then it is easily understood that the device is a functioning bridge rectifier. Furthermore, it is not necessary to connect all the probes 32 to the component if the component has less than four pins. For example, if only two probes are used, then a two-digit signature is provided.

Since the order of the signature is not important, tester 30 can include a a look-up table with a library of pre-tested components 34, so that upon generation of a signature, the controller will search the look-up table for the displayed combination of digits and display appropriate text onto text display 36. For example, if the signature <3316>, or <3613> appears, then text display 36 will present the string “Bridge Rectifier” for both signatures.

Tester 30 can also determine the maximum operating frequency of components. Tester 30 can include a frequency generator, a display for indicating the present operating frequency, or an input for receiving an external frequency generator. Once the probes 32 have been connected to the pins of the component 34, the user only needs to increment the operating frequency and initiate the test until a change occurs in the component signature displayed. Thus, the frequency at which the component signature changes value is the maximum frequency of operation of the device. Alternatively, the maximum operating frequency can be determined by observing the settling time for the outputs of the component. A predefined settling time can be set as the threshold for determining failure of the component to operate beyond a specific frequency. This particular method is preferably executed with the assistance of a computer.

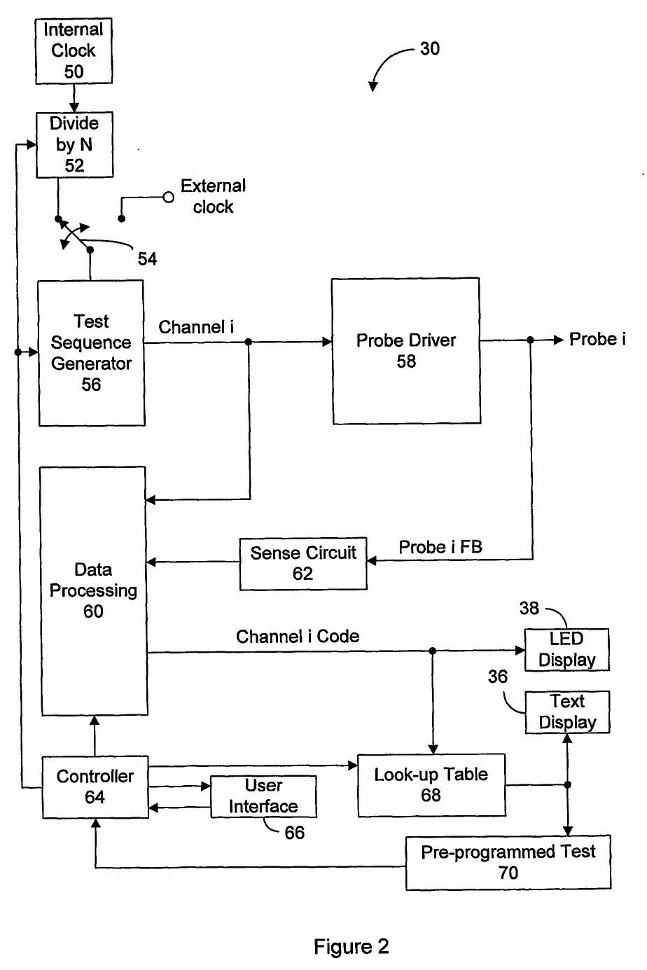

FIG. 2 is a general block diagram of an electronic component measuring instrument 30 shown in FIG. 1. However, it should be understood by those of skill in the art that the block diagram of FIG. 2 can be integrated with multimeter systems. Measuring instrument 30 includes several of the same numbered components shown in FIG. 1, namely, the text display 36 and the LED display 38. Measuring instrument 30 further includes an internal clock 50 for providing a fixed oscillating signal to a divider by N block 52. An electromechanical switch 54 selects between either the internal clock, via the divide by N block 52, or an external clock input for use by test sequence generator 56. Test sequence generator 56 controls probe driver block 58 through channel i, which is also received by data processing block 60. The signals provided by test sequence generator 56 are test signals consisting of at least one bit of information. The output of probe drivers block 58 drives a probe, Probe i, and a feedback signal Probe i FB is received by sense circuit 62. Sense circuit 62 provides an output to data processing block 60 for processing. A controller 64 controls data processing block 60, test sequence generator 56, divide by N block 52 and look-up table 68. Controller 64 also prompts and receives input from user interface block 66, and receives input from pre-programmed test block 70. Data processing block 60 sends an internal code in parallel to LED display 38 and look-up table 68. Look-up table 68 drives text display 36 and sends instructions to pre-programmed test block 70. In order to simplify the block diagram, only one channel i and corresponding Probe i, Probe i FB, Channel i code and LED display 38 are shown. In alternate embodiments of the present invention, variable “i” can be any integer number.

The functions of each block of measuring instrument 30 are discussed in further detail below. The clock circuits consist of internal clock 50, divide by N block 52 and switch 54. Internal clock 50 can include a standard oscillator integrated circuit (IC). Divide by N block 52 includes a standard clock divider circuit, and permits the test sequence generator to operate at a frequency set by the user via user interface 66 and controller 64. In this particular embodiment, the default operating frequency is 1 kHz. Optionally, the user can plug in an external clock generator to force switch 54 to connect the test sequence generator to the external clock input for performing the aforementioned maximum operating frequency test.

Test sequence generator 56 is responsible for providing signals to probe driver 58 that correspond to different voltages and currents at different times. Depending on the particular test sequence, channel i may simply control the probe drivers 58 to turn on and off at different times. Alternatively, channel i may control the probe drivers such that they apply a different voltage and current at particular times. In summary, test sequence generator 56 executes a test algorithm, which can be executed by a micro controller.

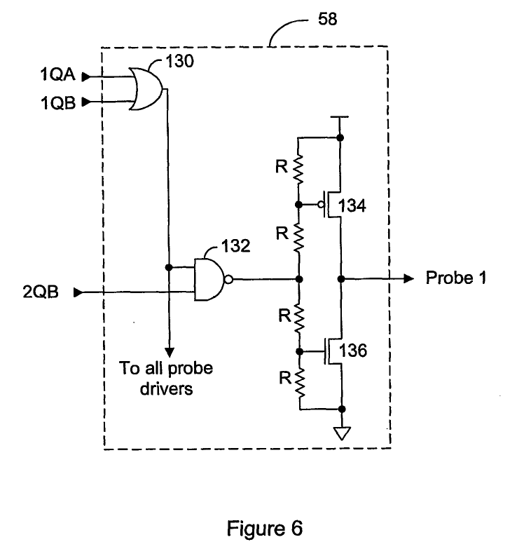

The output/input data path consists of probe driver 58 and sense circuit 62. Probe driver 58 is responsible for driving voltage and current to a pin through Probe i. Embodiments of probe driver 58 are discussed later with reference to FIGS. 6 to 8. Sense circuit 62 converts the feedback current and voltage signal from Probe i to logic levels, and can include circuits such as an A/D converter and a comparator. The sense circuit can also include a reference voltage source.

Data processing block 60 is responsible for generating an internal code representing the raw data form of the signature for a tested component. Once the internal code has been generated, it is provided to LED display 38 for the user to read in the form of a letter or number. As previously mentioned, the signature can be provided through a digital generation method or through an analog generation method. Accordingly, data processing block 60 can then include a digital processing algorithm and an analog processing algorithm, without modifying the other components of tester 30. The digital and analog processing algorithms will be discussed later in further detail. The present embodiment of tester 30 shown in FIG. 2 is presently configured for digital processing, but the tester 30 can include a switch for allowing the user to toggle between the digital test and the analog test modes. Obvious design modifications to tester 30 of FIG. 2 for incorporating switches would be implemented to provide the dual digital and analog test functionality.

Controller 64 generally coordinates and controls some of the other blocks of tester 30, and can include a micro-controller for example. User interface 66 can include various mode switches and buttons, such as a button for initiating the test. Those of skill in the art will understand that a plurality of different user interface devices can be used to allow the user to access different features and options of tester 30.

The user display section of tester 30 consists of look-up table 68, LED display 38 and text display 36. As previously mentioned, look-up table 68 outputs defined text to display via text display 36 upon matching the code from data processing block 60 to a code stored in the table. In a present embodiment, the look-up table 68 can include content addressable memory and other memories for storing codes and corresponding text. In alternate embodiments of the present invention, the codes and corresponding text can be preset or user defined through user interface 66.

The pre-programmed test block 70 can prompt the user to initiate a second test specific to an identified component from an initial test in order to obtain a second signature for the component. This can include increasing, the voltage and current delivered by the probes to the pins of the component during the second test.

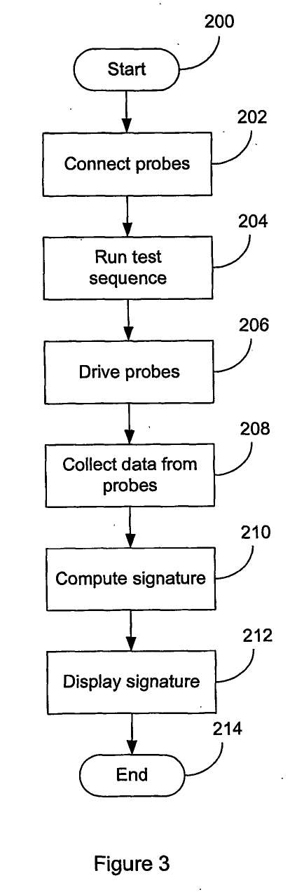

The general method of generating a signature for a component with the system shown in FIG. 2 is now described with reference to FIGS. 2 and 3.

FIG. 3 shows a flow chart of the general method of generating a signature for an electronic component according to an embodiment of the present invention. The method starts in step 200, and at step 202 the user connects the probes to the pins of an electronic component. Once the probes have been connected, a pre-programmed or preset test sequence is executed from test sequence generator 56, driving the probes with fixed or different voltages and currents at different times at step 206. Feedback voltage and current from the probes are received by the sense circuit 62, and the result of the sense circuit 62 is received by data processing block 60 at step 208. At step 210, data processing block 60 executes either the digital or analog generation processes to generate a code. Finally the code is sent to LED display 38 for communication of the signature to the user, and the method ends at step 214.

With this signature, the user will be able to identify the component from a known list of functioning components and quickly determine if the tested component is functional or non-functional.

As previously discussed, the component signature can be generated according to a digital generation process. In the digital process, a signature is generated based on the logical function of component. This algorithm determines whether or not the logic state driven by a probe changes. The test executed by the test sequence generator 56 of FIG. 2 consists of sequentially applying different logic states to the pins of the component through each probe, and detecting a change in the logic state of any probe due to the logical function of the component. This is done by comparing the logic state, ie. a logic “1” or “0”, of each probe's output with its fed back input, and summing the number of times the logic state of the probe changes. The summed value is the signature for that probe. This method of testing is ideal for testing relays, diodes, SCR, cables and connectors.

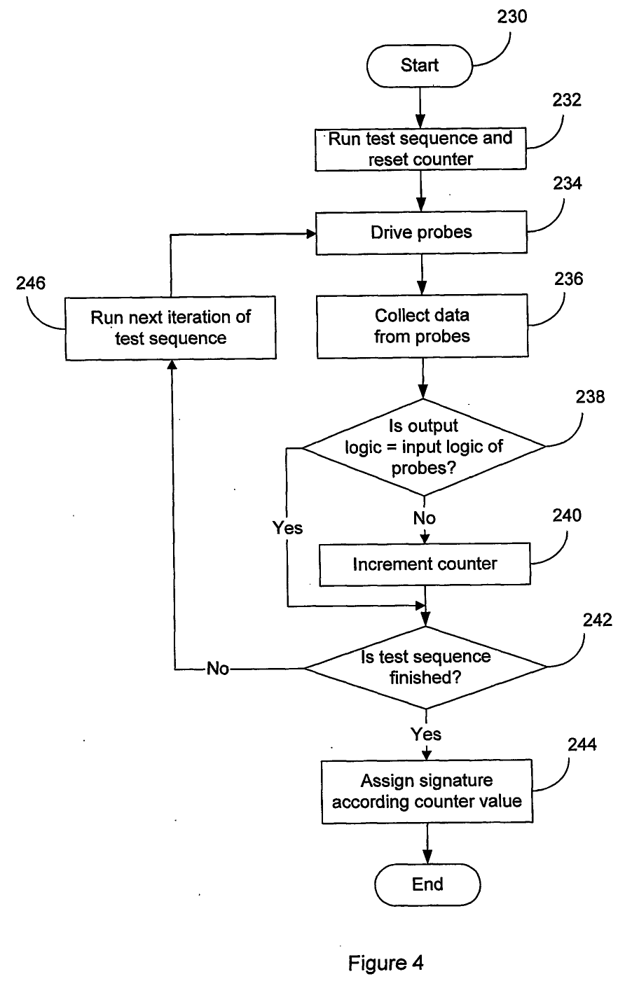

FIG. 4 is a flow chart showing the digital generation method for providing a component signature according to an embodiment of the present invention. The sequence shown in FIG. 4 is a more detailed aspect of the method presented in FIG. 3. The method starts at step 230 and a counter is reset before the preset test sequence is initiated at step 232. At step 234, the probes are each driven to a logic state according to the test pattern of the current iteration. At step 236 feedback voltage from the probes are received and converted to a representative logic state. At step 238 the logic state driven by the probe is compared to the probe feedback logic state. If they are not equal to each other, then the counter is incremented at step 240 and the process proceeds to step 242. If they are equal to each other, then the process skips step 240 and proceeds to step 242. At step 242, if the test sequence is complete, then the final signature of the probe becomes the current counter value. Otherwise, the test sequence is not complete and the next iteration of the test sequence is executed at step 246 and the probes are driven again at step 234. The process continues until all the iterations of the test sequence have been executed.

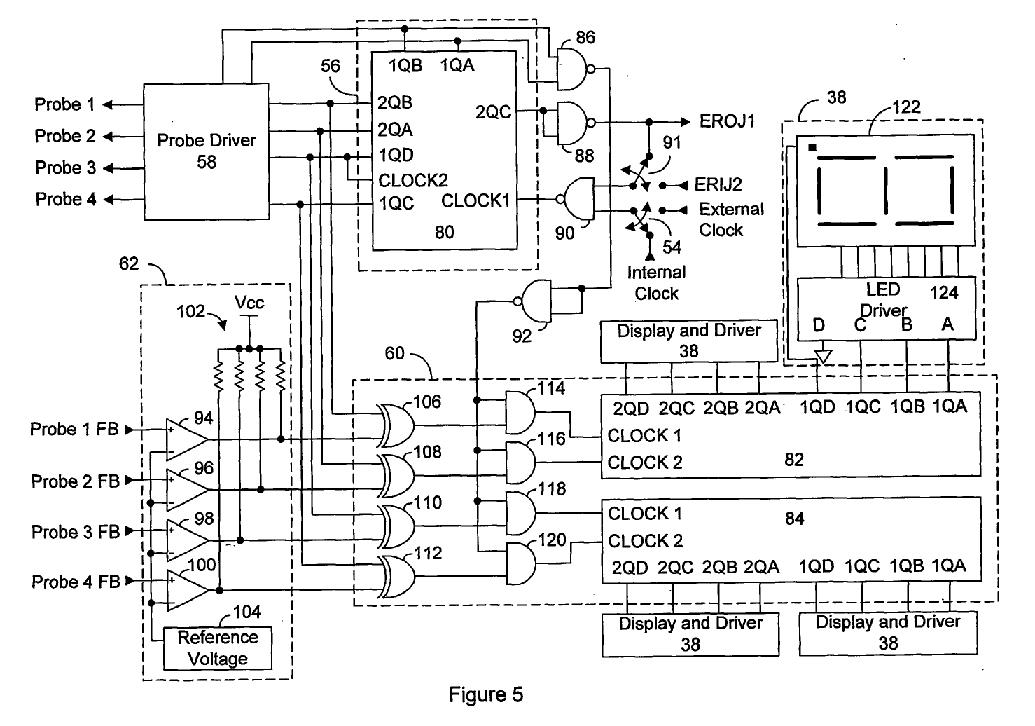

FIG. 5 shows a detailed circuit schematic of an electrical component measuring instrument according to an embodiment of the present invention. Many of the component blocks shown in FIG. 6 correspond to the same numbered elements in FIGS. 1 and 2. In particular the tester of FIG. 6 includes a test sequence generator 56, probe driver 58, data processing block 60, sense circuit 62, and LED display 38. It is noted that some components have been omitted from FIG. 6 because they are standard components that enhance the operation of the tester. In this particular embodiment, the tester has four probes for connection to a pin of a component, labelled from Probe 1 to Probe 4. Details of each component block of FIG. 6 will now be described.

Test sequence generator 56 includes a standard counter chip 80, such as a NTE74LS393 by NTE Electronics Inc., with two four-bit counters. The outputs associated with one counter are 1QA, 1QB, 1QC and 1QD with a clock input CLOCK1. The outputs associated with the other counter are 2QA, 2QB, 2QC and 2QD with a clock input CLOCK2. Counters are well known in the art, therefore a description of the operation of counters is not necessary. The 1QC, 1QD, 2QA and 2QB test signal outputs are each connected to the input of a probe driver in probe driver block 58. Each probe driver of probe driver block 58 then drives a voltage and current to each respective probe. Circuit details of the probe drivers will be described later with reference to FIG. 6. NAND gate 86 receives outputs 1QA and 1QB from counter 80 for driving the inputs of NAND gate 92. NAND gate 92 simply inverts the logic state of the output of NAND gate 86 for driving a first input of each AND gate 114, 116, 118 and 120. The output of gate 92 allows AND gates 114, 116, 118 and 120 to pass the logic state of their respective second inputs. NAND gate 88 configured as an inverter inverts the 2QC output of counter 80 for driving signal EROJ1, an external read number output jack. The output of NAND gate 90 is connected to the CLOCK1 input of counter 80, and has a first input connected to switch 91 and a second input connected to switch 54. Switch 91 is the same type of switch as switch 54, previously described in FIG. 2. Switch 91 can couple the input of NAND gate 90 to either EROJ1 or signal ERIJ2, which is an external read number control input jack. Signals EROJ1 and ERIJ2 are used for connecting testers together in a daisy chain configuration. For example, if two testers were to be used together, the EROJ1 output of the first tester would be connected to the ERIJ2 of the second tester. This configuration ensures that the second tester finishes executing its test sequence before the first tester finishes executing its test sequence.

Sense circuit 62 includes four comparators 94, 96, 98 and 100, such as an NTE834 by NTE Electronics Inc., and load circuit 102 connected to the outputs of each comparator. Probe feedback signals Probe1FB, Probe2FB, Probe3FB and Probe4FB are connected to the first input of comparators 94, 96, 98 and 100 respectively, and the second input of each comparator receives a reference voltage generated by reference voltage generator 104. The load circuit is required because the outputs of comparators 94, 96, 98 and 100 are open-collector terminals. Reference voltage generator provides a reference voltage that is approximately half the voltage level of a full logic “1”. In an alternative embodiment, reference voltage generator 104 can provide several different reference voltages depending on the technology of the tested component. For example, the reference voltage can be changed by the user for components fabricated with Germanium and Gallium Arsenide. By changing the reference voltage used by comparators 94, 96, 98 and 100, a different signature for the same component can be generated so that each component can have a set of signatures to further distinguish it from other components. Therefore depending on the result of the comparison, each comparator will output a logic level representing the state of its probe feedback signal relative to the reference voltage. Additionally, by performing tests across different reference voltages, some of which will be even more relevant to the behaviour of the component, the tester reveals finer detail such as faint leaks, and enhances the ability of the tester to identify components with various voltage drops at their P-N junctions. Practical applications include detecting faint leaks in high impedance components, differentiating the base impedance of short-circuits and zener diodes. Methods of generating references voltages and switching between the different reference voltages are well known in the art and hence do not require further discussion.

Data processing block 60 includes four XOR gates 106, 108, 110 and 112, each having one input connected to a respective comparator output. The second input of XOR gates 106, 108, 110 and 112 are connected to output signals 2QB, 2QA, 1QD and 1QC respectively. The output of each XOR gate is connected to the second inputs of AND gates 114, 116, 118 and 120 respectively. As previously mentioned, AND gates 114, 116, 118 and 120 serve as pass gates for passing the logic level of each XOR gate output when their first inputs are at the high logic level. Data processing block 60 also includes two more counter chips 82 and 84, identical to counter chip 80. Counter chip 82 receives the output of AND gate 114 at its CLOCK1 input and the output of AND gate 116 at its CLOCK2 input. Counter chip 84 receives the output of AND gate 118 at its CLOCK1 input and the output of AND gate 120 at its CLOCK2 input. The 1QD, 1QC, 1QB, 1QA and 2QD, 2QC, 2QB, 2QA outputs of both counter chips 82 are connected to respective display and driver blocks 38. Each display and driver block 38 includes an LED driver 124 having its A, B and C inputs connected to the 1QA, 1QB and 1QC outputs of counter chip 82 respectively, while the D input of LED driver 124 is not used and grounded. The 1QD output of counter chip 82 is connected directly to the “dot” segment of LED display 122, and the outputs of LED driver 124 are connected to respective LED segments of display 122. Generally, each XOR gate compares the output signal corresponding to one probe to the comparator output associated with that probe. If the logic levels are different, then the XOR gate outputs a “1” logic level to increment the counter associated with the probe, via its clock input. Those of skill in the art will understand that the XOR gates shown represent logic circuitry that can be arranged in a variety of configurations to provide an XOR function.

Mapping of the counter value to the display can be done in a variety of known methods. Table 1 below illustrates possible mappings of the counter to a user recognizable character generated on a display for a four probe test system.

TABLE 1

| | Display: | Display: | | |
|---|---|---|---|---|
| | Decimal + | Hexadecimal | | |
| Number of | point | code | | Display: |
| logical | normalised | normalized to | | Octal |
| transitions | to 16 | 16 | Display: Binary fractions | (Modulo 8 + point) |
| 0 | 0 | 0 | 0/16 ═> .0000 ═> ._0 | ._{—} |
| 1 | 1 | 1 | 1/16 ═> .0001 ═> 1 | .1 |
| 2 | 2 | 2 | 2/16 ═> .0010 ═> 2 | .2 |
| 3 | 3 | 3 | 3/16 ═> .0011 ═> 3 | .3 |
| 4 | 4 | 4 | 4/16 ═> .0100 ═> 4 | .4 |
| 5 | 5 | 5 | 5/16 ═> .0101 ═> 5 | .5 |
| 6 | 6 | 6 | 6/16 ═> .0110 ═> 6 | .6 |
| 7 | 7 | 7 | 7/16 ═> .0111 ═> 7 | .7 |
| 8 | 8 | 8 | 8/16 ═> .1000 ═> 8 | 0 |
| 9 | 9 | 9 | 9/16 ═> .1001 ═> 9 | 1 |
| 10 | .0 | A | 10/16 ═> .1010 ═> A | 2 |
| 11 | .1 | B | 11/16 ═> .1011 ═> B | 3 |
| 12 | .2 | C | 12/16 ═> .1100 ═> C | 4 |
| 13 | .3 | D | 13/16 ═> .1101 ═> D | 5 |
| 14 | .4 | E | 14/16 ═> .1110 ═> E | 6 |
| 15 | .5 | F | 15/16 ═> .1111 ═> F | 7 |
| 16 | .6 | G | 16/16 ═> .0000 ═> G | ._{—} |

FIG. 6 shows a single probe driver circuit of probe driver block 58 of FIG. 5. It is not necessary to show additional probe driver circuits because all the probe driver circuits of probe driver block 58 are identical to each other. Probe driver block includes an OR gate 130 that receives output signals 1QA and 1QB from counter chip 80 of FIG. 5. The output of OR gate 130 is connected to a first input of NAND gate 132, and the NAND gates of other probe drivers in probe driver block 58. The second input of NAND gate 132 is connected to the 2QB output of counter chip 80, and the output of NAND gate 132 is connected to the voltage-divider-resistor network consisting of serially connected resistors R. P-channel transistor 134 and N-channel transistor 136 form a complementary pair of an inverter circuit, each having its gate connected to the voltage-divider-resistor network, for driving Probe 1. The value of R can be the same or different, depending on the amount of current desired for application to the probe. Alternatively, a voltage-divider-resistor network is not necessary because the sizes of transistors 134 and 136 can be adjusted to obtain different currents. Those of skill in the art will understand that there are many different configurations for controlling the current from the probe driver circuit.

FIG. 6 presented one type of probe driver circuit that can be used in the tester system for generating a unique current and voltage for the probes. According to an alternate embodiment of the present invention, the probe driver can generate different currents and voltages for the probes.

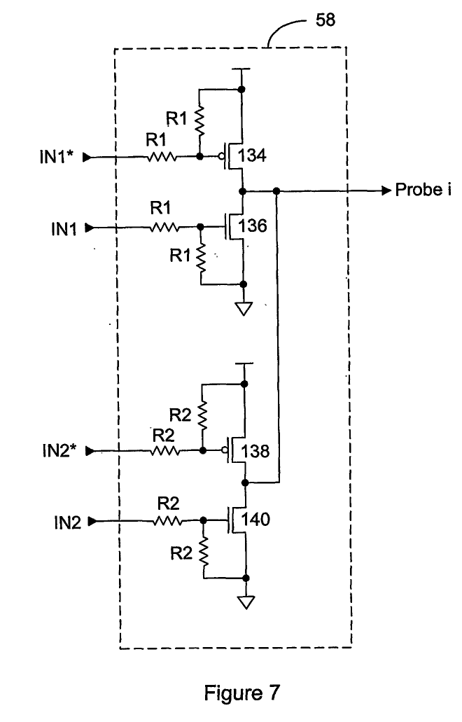

FIG. 7 is a circuit schematic of probe drivers for a single probe. The circuit of FIG. 7 includes two tri-state inverters, each coupled to its own voltage-divider-resistor network. The first tri-state inverter includes a complementary pair of transistors consisting of p-channel transistor 134 and n-channel transistor 136, for driving Probe i. The voltage-divider-resistor network of the first tri-state inverter includes resistors R1 having a predetermined value, such that when test signals IN1* and IN1 are at the low and high logic levels respectively, the first tri-state inverter will drive Probe i with a first current. The second tri-state inverter is identical in configuration as the first tri-state inverter, and includes a complementary pair of transistors consisting of p-channel transistor 138 and n-channel transistor 140, for driving Probe i. The second tri-state inverter will generate a different current than the first tri-state inverter because of the different values of its resistors R2, in response to test signals IN2* and IN2 at the low and high logic levels respectively. Test signals IN1*, IN1, IN2* and IN2 can be generated from a microcontroller in alternate embodiments of the present invention. Those of skill in the art will understand that IN1* and IN1 are complementary signals, as are signals IN2* and IN2, and that several such drivers can be connected in parallel to each other.

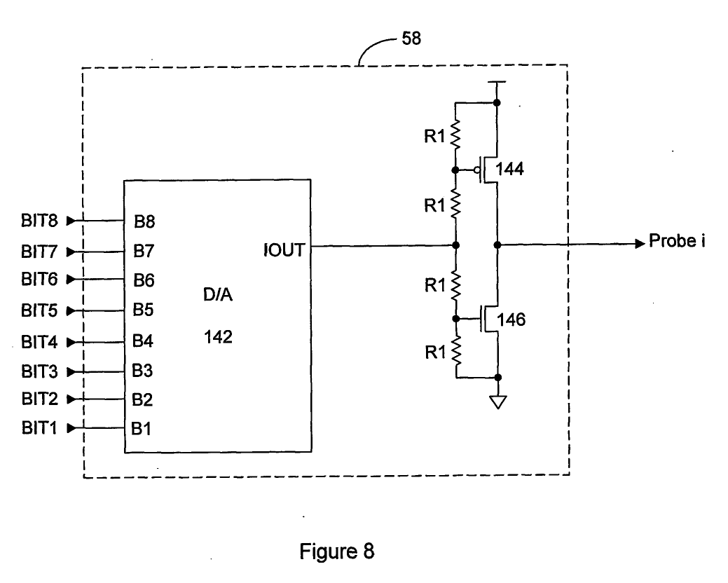

FIG. 8 shows another alternate embodiment of the probe driver block 58 of FIG. 5 for generating different currents for a single probe. This circuit includes a D/A converter 142, and a complementary pair of transistors 144 and 146 connected to a voltage-divider-resistor network having resistors with a value of R1. D/A converter 142 receives test signals in the form of an eight-bit word, BIT1 to BIT8, and generates a current through its IOUT output corresponding to the word. The configuration of the transistors 144 and 146 and its voltage-divider-resistor network is identical to that shown in FIG. 6. Hence many different currents can be generated for the probe. Signals BIT1 through BIT8 can be generated by a microcontroller in alternate embodiments of the present invention. It is noted that OR gate 130 and NAND gate 132 are not shown in FIGS. 7 and 8, but those of skill in the art will understand that the circuits of FIGS. 7 and 8 can be configured with OR gate 130 and NAND gate 132 to provide the same enabling function shown in FIG. 6.

Therefore by changing the current and voltage applied by the probes, more distinct signatures can be generated for any electronic component. In an application of the tester, the user can initiate a standard test sequence to identify the component and then initiate a specific test for that component in which the standard test is run again but with the probes injecting higher current. Alternatively, the test sequence can be configured to change the voltage and current levels of the probes at each iteration of the test sequence.

In the particular embodiment of FIG. 5, the test sequence generator simply sweeps all possible probe logic state combinations. Table 2 below lists the operation of the measuring instrument of FIG. 5 for different combinations of outputs 1QA, 1QB, and 2QC. An “X” indicates that the logic state of the parameter can be either “0” or “1”.

TABLE 2

| Output | Output | Output | Output | Output | Output | Output | |
|---|---|---|---|---|---|---|---|
| 2QC | 2QB | 2QA | 1QD | 1QC | 1QB | 1QA | Reaction |
| 0 | X | X | X | X | 0 | 0 | Discharge probes |
| 0 | X | X | X | X | 0 | 1 | Drive probes |
| 0 | X | X | X | X | 1 | 0 | Drive probes |
| 0 | X | X | X | X | 1 | 1 | Pass result of logic |
| | | | | | | | comparison to |
| | | | | | | | counters |
| 1 | X | X | X | X | X | X | End of test; display |
| | | | | | | | results |

The first four lines of Table 2 occur for each iteration of the test, or for each different logic state combination of 1QC, 1QD, 2QA and 2QB. It should be noted that only one of the second and third lines of Table 2 occurs for each iteration of the test. OR gate 130 of FIG. 6 permits either condition of the second and third lines of Table 2 to enable the probe driver circuits. Discharging the probes before commencement of the next iteration ensures that residual charge and current of the probes are removed for accurate testing.

To further illustrate the operation of the tester of FIG. 5, an example whereby a 2-input AND gate is tested is now discussed with reference to Table 3 below. In this example, probe 1 and probe 2 are connected to the two inputs of the AND gate, and probe 3 is connected to the output of the AND gate, leaving probe 4 unconnected and in the high impedence state. Table 3 lists the logic states, voltage and current levels for each of the probes when driven, and the feedback voltage and current levels of each of the probes as well as the resulting feedback logic state of the probes based on the feedback voltage level. In the first iteration probe 1, probe 2 and probe 3 are driven to the “0”, “1” and “0” logic levels respectively. Since the logic levels of the probes match the logic function of the AND gate, there are no significant changes to the voltage and current levels of the probes. Therefore none of the counters associated with each probe are incremented. In iteration 2 the applied logic states of the probes are changed such that probes 1 and 2 are both driven to the logic “1” states and probe 3 is driven to the “0” logic state. The output of the AND gate will therefore drive its output to the “1” logic state, hence the feedback voltage and current of probe 3 changes. Consequently, the counter associated with probe 3 increments and the display of the tester will read <_,_{—}, 1,_>.

TABLE 3

| | V Probe 1 | I Probe 1 | V Probe 2 | I Probe 2 | V Probe 3 | I Probe 3 | V Probe 4 | I Probe 4 |
|---|---|---|---|---|---|---|---|---|
| Iteration | | | | | | | | |
| Logic state | 0 | | 1 | | 0 | | 0 | |
| driven | | | | | | | | |
| Voltage/Current | 0.0 volts | 5.0 ma | 5.0 volts | 4.0 ma | 0.0 volts | 5.0 ma | 0.0 volts | 5.0 ma |
| driven | | | | | | | | |
| Feedback | 0.1 volts | 0.1 ma | 4.8 volts | 0.2 ma | 0.1 volts | 0.0 ma | 0.0 volts | 0.0 ma |
| voltage/current | | | | | | | | |
| Feedback logic | 0 | | 1 | | 0 | | 0 | |
| state | | | | | | | | |
| Counter value | 000 | | 000 | | 000 | | 000 | |
| Display | “_” | | “_” | | “_” | | “_” | |
| Iteration 2 | | | | | | | | |
| Logic state | 1 | | 1 | | 0 | | 0 | |
| driven | | | | | | | | |
| Voltage/Current | 5.0 volts | 4.0 ma | 5.0 volts | 4.0 ma | 0.0 volts | 5.0 ma | 0.0 volts | 5.0 ma |
| driven | | | | | | | | |
| Feedback | 4.8 volts | 0.2 ma | 4.8 volts | 0.2 ma | 4.3 volts | 5.0 ma | 0.0 volts | 0.0 ma |
| voltage/current | | | | | | | | |
| Feedback logic | 1 | | 0 | | 1 | | 0 | |
| state | | | | | | | | |
| Counter value | 000 | | 000 | | 001 | | 000 | |
| Display | “_” | | “_” | | “1” | | “_” | |

As previously mentioned, the signature of a component can be provided through an analog generation method. In this method, a signature is generated based on the waveform response of the component. Specific parameters are calculated as a function of the waveform of each output to capture or characterize the distinctiveness of the waveform. Each calculated parameter is then mapped to a character recognizable by the user. The resulting set of characters is the signature for that component. This test can be used to gauge the age of components such as capacitors, resistors, diodes and zener diodes, and can be used to identify the equivalent circuit model between two points of verification.

The following are possible parameters that can be used for quantifying the waveform response, also known as a pulse:

Duration of the pulse

Frequency of the pulse

Sum of the absolute values of the durations of the voltages of the pulse

Ratio of the surface of the pulse as a function of time between the centre of two points of synchronisation, and the location where the surface of the signal corresponds to half of the total surface area of the pulse. This location is termed as the point of equilibrium of the surface of the pulse.

Gravitational point of the pulse or the point of inertia of the surface

Dis-symmetry of the pulse

Maximum and minimum proportions to the percentage of the duration of the pulse, whose values will be used to normalize the signal in amplitude.

The breaking down of the pulse into three vectors dephased by 120 degrees

Determination of the characteristic polynome of the pulse

Compression and numerical manipulation of the pulse (slang function)

The relative sum of the Fourrier transform of the normalized pulse

Calculation of the surface of the pulse filtered at T/2, T/3, T/4 etc.

Although any of the aforementioned parameters can be used, there are certain considerations that should be taken into account to properly measure the importance of each parameter. Some of these considerations are listed below:

The probability of error in characterizing a waveform or pulse with respect to existing instruments should be minimized.

The ease of extraction of the temporal dimension of a signal

The speed of calculation should be maximized

The precision of the measurements necessary for various applications should be maximized

The overall significance of each part of the signature should be high

The length of the desired signature

The signatures of the most common signals, such as sinusoidal signals, are distinct from one another

Minimizing the amount of information entered into the tester by the user

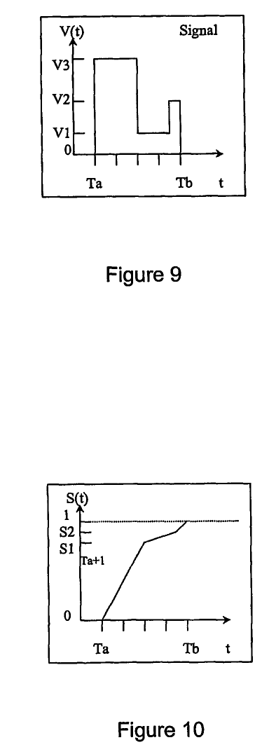

From an analysis of the parameters and the desired criteria, three parameters were chosen for calculating values for the component signature. The first is the absolute surface area (S) of the pulse, the second is the length (L) of the function of the absolute surface area of the pulse, and the third is the distribution (D) of the absolute surface area of the pulse. Hence if a pulse is defined as a section of a signal which is limited by two consecutive synchronization points, then it will have a voltage V(t) as measured at the probe between the first synchronization point Ta, and the second synchronization point Th. An example of a pulse is shown in FIG. 9. FIG. 10 is a plot of distribution of the absolute surface area of the pulse of FIG. 9.

The value of S is calculated from equation 1.

Equation 1:

$$S = {F}_{n} \times {\int }_{{T}_{a}}^{{T}_{b}} V ( t ) ⅆ t$$

The value of L is calculated from equation 2.

Equation 2:

$$L = {\int }_{{T}_{a}}^{{T}_{b}} ( \sqrt{{( ⅆ s / ⅆ t )}^{2} + 1} ) ⅆ t$$

The value of D is calculated from equation 3.

Equation 3:

$$D = {\int }_{{T}_{a}}^{{T}_{b}} S ( t ) ⅆ t$$

Where

$$S ( t ) = \frac{{F}_{n}}{S} \times {\int }_{{T}_{a}}^{t} V ( t ) ⅆ t$$

and

$${F}_{n} = \frac{1}{{V}_{max} \times ( {T}_{b} - {T}_{a} )} ,$$

where Fn is a normalization factor.

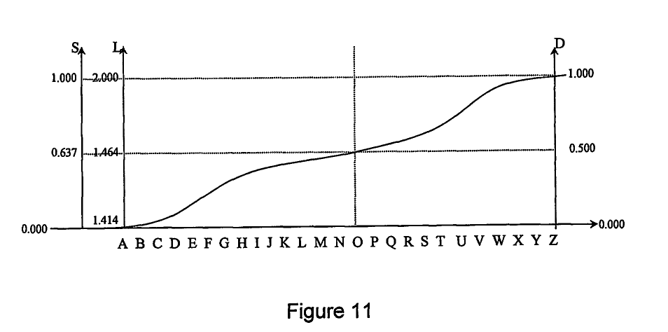

Once the values of S, L and D have been computed, they can be mapped to provide the user with readable characters. An example of a mapping function for S, L and D is shown in FIG. 11. The mapping function of FIG. 11 is non-linear to ensure that the most common signals, numerical, sinusoidal, and square signals, are distinguished amongst themselves by way of the flatter distribution around “A” for numerical signals, “0” for sinusoidal signals, and “Z” for square signals. If for example the calculated values for S=0.656, L=1.470, and D=0.623, then the character displayed to the user will be <SPS>. Of course, parameters other than S, L and D can be used in different combinations for characterizing the waveform response of the tested component.

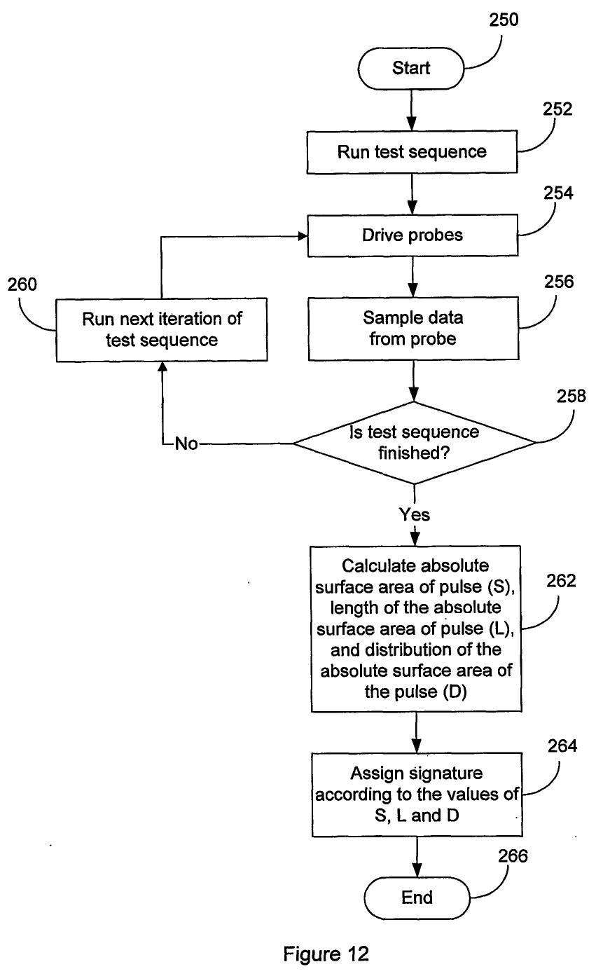

FIG. 12 shows a flow chart illustrating the analog generation method for providing a component signature according to an embodiment of the present invention. The method starts at step 250 and a test sequence is initiated at step 252. It is preferred that the test sequence includes applying a known test waveform to the pin of the device. The probes are then driven at step 254 with a preset current and voltage. At step 256 a feedback response from the probe is sampled and stored in memory. At step 258, the process determines if the test sequence is finished. If the test sequence is not finished, then the process proceeds to step 260 where the next iteration of the test sequence is executed. Otherwise, the process proceeds to step 262 where the values for S, L and D are calculated. In step 264 the values of S, L and D are separately mapped according to the mapping function of FIG. 11 to provide the corresponding characters for display.

Preferably, an optional sorting step can be executed before step 262 to increase the accuracy of the signature for further distinguishing a component. The sorting step obviates the likelihood of assigning different signatures to the same component following different connections of the probes to the pins between tests. In the sorting step, output samples are sorted according to a scheme which ensures that different connections of the probes to the pins of a component result in the generation of same parameters and, consequently, the same signature. An example of the sorting step is discussed with reference to Tables 4, 5 and 6.

Table 4 below lists the logic states applied to channels 1 through 4 in each iteration of a test sequence.

TABLE 4
Test sequence

Logic applied

| Iteration # | Channel4 | Channel3 | Channel2 | Channel1 |
|---|---|---|---|---|
| 0 | 0 | 0 | 0 | 0 |
| 1 | 0 | 0 | 0 | 1 |
| 2 | 0 | 0 | 1 | 0 |
| 3 | 0 | 0 | 1 | 1 |
| 4 | 0 | 1 | 0 | 0 |
| 5 | 0 | 1 | 0 | 1 |
| 6 | 0 | 1 | 1 | 0 |
| 7 | 0 | 1 | 1 | 1 |
| 8 | 1 | 0 | 0 | 0 |
| 9 | 1 | 0 | 0 | 1 |
| 10 | 1 | 0 | 1 | 0 |
| 11 | 1 | 0 | 1 | 1 |
| 12 | 1 | 1 | 0 | 0 |
| 13 | 1 | 1 | 0 | 1 |
| 14 | 1 | 1 | 1 | 0 |
| 15 | 1 | 1 | 1 | 1 |

Table 5 below lists the sample number for each channel in each iteration. Each sample number can represent a sampled voltage or current value.

TABLE 5
Output samples

Channel_{samplenumber}

| Iteration # | Channel4 | Channel3 | Channel2 | Channel1 |
|---|---|---|---|---|
| 0 | C4₀ | C3₀ | C2₀ | C1₀ |
| 1 | C4₁ | C3₁ | C2₁ | C1₁ |
| 2 | C4₂ | C3₂ | C2₂ | C1₂ |
| 3 | C4₃ | C3₃ | C2₃ | C1₃ |
| 4 | C4₄ | C3₄ | C2₄ | C1₄ |
| 5 | C4₅ | C3₅ | C2₅ | C1₅ |
| 6 | C4₆ | C3₆ | C2₆ | C1₆ |
| 7 | C4₇ | C3₇ | C2₇ | C1₇ |
| 8 | C4₈ | C3₈ | C2₈ | C1₈ |
| 9 | C4₉ | C3₉ | C2₉ | C1₉ |
| 10 | C4₁₀ | C3₁₀ | C2₁₀ | C1₁₀ |
| 11 | C4₁₁ | C3₁₁ | C2₁₁ | C1₁₁ |
| 12 | C4₁₂ | C3₁₂ | C2₁₂ | C1₁₂ |
| 13 | C4₁₃ | C3₁₃ | C2₁₃ | C1₁₃ |
| 14 | C4₁₄ | C3₁₄ | C2₁₄ | C1₁₄ |
| 15 | C4₁₅ | C3₁₅ | C2₁₅ | C1₁₅ |

Table 6 below lists the sorted sample numbers according to the present sorting scheme.

TABLE 6
Sorted output samples

Channel_{samplenumber}

| Iteration # | Channel4 | Channel3 | Channel2 | Channel1 |
|---|---|---|---|---|
| 0 | C4₁₅ | C3₁₅ | C2₁₅ | C1₁₅ |
| 1 | C4_{14*} | C3_{14*} | C2_{14*} | C1_{13*} |
| 2 | C4_{13*} | C3_{13*} | C2_{11*} | C1_{11*} |
| 3 | C4_{11*} | C3_{7*} | C2_{7*} | C1_{7*} |
| 4 | C4_{6**} | C3_{10**} | C2_{12**} | C1_{12**} |
| 5 | C4_{5**} | C3_{9**} | C2_{9**} | C1_{10**} |
| 6 | C4_{3**} | C3_{3**} | C2_{5**} | C1_{6**} |
| 7 | C4₈ | C3₄ | C2₂ | C1₁ |
| 8 | C4₇ | C3₁₁ | C2₁₃ | C1₁₄ |
| 9 | C4_{12***} | C3_{12***} | C2_{10***} | C1_{9***} |
| 10 | C4_{10***} | C3_{6***} | C2_{6***} | C1_{5***} |
| 11 | C4_{9***} | C3_{5***} | C2_{3***} | C1_{3***} |
| 12 | C4_{4****} | C3_{8****} | C2_{8****} | C1_{8****} |
| 13 | C4_{2****} | C3_{2****} | C2_{4****} | C1_{4****} |
| 14 | C4_{1****} | C3_{1****} | C2_{1****} | C1_{2****} |
| 15 | C4₀ | C3₀ | C2₀ | C1₀ |

For example, in the fifth iteration of Table 4, logic states <0,1,0,1>are applied to channels 4 through 1, respectively. During that fifth iteration, responses from the probes are sampled, as shown in Table 5, resulting in the output samples <C4₄, C3₄, C2₄, C1₄>. Once all the iterations have been executed, the samples are re-ordered within their respective channel, grouped within their channel, and finally sorted in decreasing order within their groups, as illustrated in Table 6. In Table 6, samples belonging to a group are identified by having the same number of asterixes. For example, if the sampled values for channel 3 sample numbers C3₁₄, C3₁₃, C3₇ are 13, 18, 6 respectively, their sorted sequence would therefore be 18, 13, 6.

In an alternative embodiment of the present invention, additional component signature information regarding the tested component can be provided. The displayed signature representing the S, L and D values can be considered to represent a family of components sharing the same range of S, L and D values. Hence to obtain further details of the specific component, the user can toggle a switch to view the actual calculated values for S, L and D.

According to another embodiment of the present invention, the probes can be attached to nodes of a circuit while the circuit is in operation for generating a signature, instead of having the tester generate a reference waveform. Hence the test sequence generator 56 and probe drivers 58 are not used in this mode of operation. This test is useful for calibrating systems having variable components, such as potentiometers for example. In such a test, a signature of the system is first obtained, followed by adjusting the variable components until the displayed signature changes to a desired signature, such as the signature for a properly functioning system. Furthermore, by sampling the in operation waveform of the component, the tester can characterize the waveform in terms of its amplitude, period etc. In order to sample the waveform of the circuit, the component measuring instrument of FIG. 2 can be modified to include a synchronization circuit for triggering onto the waveform, or can be modified to receive an external trigger. In the block diagram of FIG. 2, the controller 62 can provide the synchronization function. Naturally, the appropriate functions for characterizing the waveform would be incorporated into the data processing block of the tester. In otherwords, the tester can perform the same function as an oscilloscope and provide the same information to a user in place of a signal trace. For example, the tester can inform the user that a signal is an undeformed sinusoid and has a peak AC voltage of 117 volts with a frequency of 60 Hz. If the signal is a deformed sinusoid, the tester can quantify the amount of the deformation.

The probes of the tester system shown in FIG. 1 can be adapted to improve the functionality of the tester in alternate embodiments of the present invention. For example, in the digital generation method, the accuracy of the tester can be augmented by using a probe having non-linear characteristics.

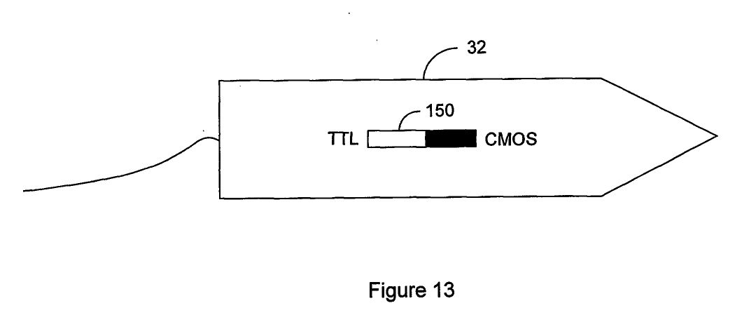

FIG. 13 shows a schematic of a probe 32 that exhibits non-linear characteristics. This probe specifically has a CMOS-TTL switch to determine the mode in which the probe is to operate in.

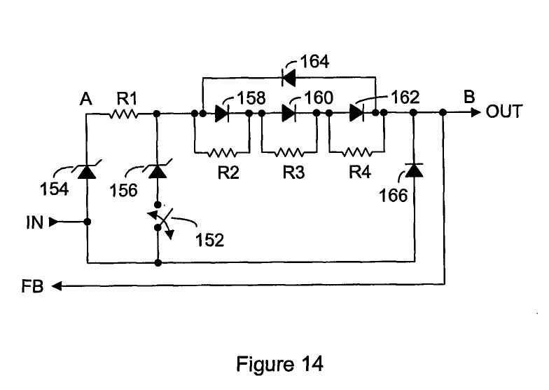

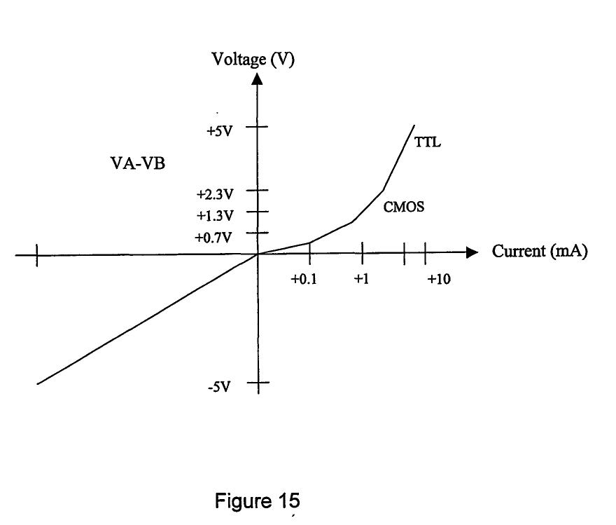

FIG. 14 shows a circuit schematic of probe 32 from FIG. 13. The probe input IN is connected to the input terminal of zener diode 154, diode 166 and switch 152. Switch 152 is coupled to switch 150 of FIG. 13 for setting the probe in either the CMOS or TTL modes. The other terminal of switch 152 is connected to the input terminal of zener diode 156. The output terminal of zener diode 154 is connected to a first terminal of resistor R1, whose second terminal is connected to the output terminal of zener diode 156. The second terminal of resistor R1 is also connected to the input terminal of diode 158 and the output terminal of diode 164. Diode 158 is connected in series with diodes 160, 162, and 164, where resistors R2, R3 and R4 are each connected in parallel with diodes 158, 160 and 162 respectively. Diodes 158, 160 and 162 and resistors R2, R3 and R4 form a non-linear circuit. The output terminal of diode 162 is connected to the probe output OUT and the output terminal of diode 166. A return feedback path FB is connected to the probe output OUT. Resistor R1 is effectively bypassed when switch 152 is closed to set the probe in the TTL mode, and the values of R2, R3 and R4 are selected such that R4>R3>R2. The V-I characteristic curve for the probe circuit of FIG. 14 is shown in FIG. 15.

In circumstances where high voltage components are to be tested, it is not practical to fix the probe driver outputs of the tester at high voltage levels because most electronic components to be tested have much lower maximum input voltage levels which can be damaged if high voltage levels are used. Hence the tester drives its probes with a relatively low voltage to prevent damaging most low voltage electronic components. Therefore to test the high voltage components, a probe can be designed with a built-in amplifier and power source for proper testing of that component.

Different probes can be designed to permit testing and waveform quantification of temperature, optical signals, audio signals, electrical or magnetic fields, and gas pressure for example, without having to change the tester itself By providing a multitude of probes for different applications, the cost of the tester can be minimized.

Various applications and embodiments of the present invention can be realized. For example, the tester can automatically detect when less probes than the maximum number of probes are in use. Then the measuring instrument can shut off the probe drivers for the unused probes, thus reducing power consumption and the time required for the tester to run its test. The probe drivers shown in FIG. 2 can be integrated into the probes for reducing the cost of the measuring instrument. The logic circuitry of FIG. 5 can be configured to increment the probe counters when the logic level of a test signal and the comparator output are the same. Multiple measuring instruments can be used in series with each other to test a component having a large number of pins. Alternatively the user can also use several measuring instruments in parallel to test more than one component at a time.

The embodiments of the present invention will allow users to identify and verify electronic components without requiring any knowledge of the electronic component or the way in which the testing is performed. Hence determination of the status of an electronic component is quick, accurate and user-friendly. Because the measuring instrument according to the embodiments of the present invention generates its own signature for a component, new components manufactured with future technologies can be identified and verified without any modification to the measuring instrument. The measuring instrument can include pre-programmed signatures for existing components, and a memory for allowing the user to enter signatures for new components.

The measuring instrument according to embodiments of the present invention can be manufactured with inexpensive common electronic components, which reduces the overall cost of the measuring instrument. As previously discussed, the measuring instrument can be integrated with existing measuring devices such as multimeters, and the circuits of the measuring instrument can be fabricated and integrated onto a single chip to reduce the form factor of the measuring instrument. The measuring instrument permits users to quickly and effortlessly determine if an electrical component or system is functions appropriately or not.

Embodiments of the present invention can be used in repair shops, technical schools, universities, research centres, hospitals, electrical and electronic stores.

The above-described embodiments of the present invention are intended to be examples only. Alterations, modifications and variations may be effected to the particular embodiments by those of skill in the art without departing from the scope of the invention, which is defined solely by the claims appended hereto.

What is claimed is:

1. An electrical component measuring instrument for generating a signature corresponding to the electrical component, the measuring instrument having probes for connecting to pins of an electrical component, a display for presenting characters, and a clock, comprising:
a test sequence generator, receiving a clock signal for generating a test sequence of test signals;
probe drivers for receiving the test signals and applying current and voltage to the probes; and,
a data processing unit for receiving data corresponding to feedback current and voltage from each of the probes and executing functions upon the data to generate a code, the data processing unit providing the code to the display.

2. The electrical component measuring instrument of claim 1, wherein the frequency of the clock signal is variable.

3. The electrical component measuring instrument of claim 1, wherein the data include logic signals corresponding to the feedback current and voltage.

4. The electrical component measuring instrument of claim 3, wherein a sense circuit receives the feedback current and voltage for generating the logic signals.

5. The electrical component measuring instrument of claim 4, wherein the sense circuit receives a reference voltage from a reference voltage generator.

6. The electrical component measuring instrument of claim 4, wherein the sense circuit includes a comparator.

7. The electrical component measuring instrument of claim 4, wherein the sense circuit includes an A/D converter and a sample and hold circuit.

8. The electrical component measuring instrument of claim 3, wherein the test sequence generator includes a counter circuit for providing the test signals.

9. The electrical component measuring instrument of claim 8, wherein the data processing unit includes logic circuitry for comparing the logic signals to the test signals, and probe counters for counting the difference in number of the logic signals and the test signals in the test sequence, the probe counters providing the code corresponding to the value of the probe counters.

10. The electrical component measuring instrument of claim 9, wherein the logic circuitry includes XOR logic for determining the difference.

11. The electrical component measuring instrument of claim 1, wherein a look-up table displays additional text corresponding to the code.

12. The electrical component measuring instrument of claim 1, wherein the probe drivers each include an inverter circuit.

13. The electrical component measuring instrument of claim 1, wherein the probe drivers each include at least two tri-state inverter circuits connected in parallel.

14. The electrical component measuring instrument of claim 1, wherein the probe drivers each include a D/A converter for providing a variable current to an inverter circuit.

15. An electrical component measuring instrument, for generating a signature corresponding to the electrical component, the measuring instrument including at least one probe for connection to pins of an electrical component and a display for presenting a character corresponding to the at least one probe, comprising:
a counter for generating an output logic signal;
a probe driver for receiving the output logic signal and driving the at least one probe according to the state of the output logic signal;
a sense circuit for receiving voltage feedback from the at least one probe and generating an input logic signal;
logic circuitry for comparing the output logic signal to the input logic signal; and,
a probe counter having a probe counter value that is incremented when the output logic signal and the input logic signal differ, the display displaying the character corresponding to the incremented probe counter value.

16. The electrical component measuring instrument of claim 15, wherein the at least one probe driver includes an inverter circuit.

17. The electrical component measuring instrument of claim 15, wherein the sense circuit includes a comparator and a reference voltage circuit.

18. The electrical component measuring instrument of claim 15, wherein the logic circuitry includes XOR logic.

19. A method for generating a signature for an electrical component comprising:
a) driving probes connected to the electrical component in each iteration of a test sequence;
b) collecting feedback data from the probes in each iteration;
c) computing a code corresponding to the feedback data; and,
d) displaying the signature corresponding to the code.

20. The method of claim 19, wherein the step of driving includes driving the probes with different current and voltage levels.

21. The method of claim 19, wherein the step of collecting includes converting the feedback data into logic levels.

22. The method of claim 19, wherein the step of computing includes comparing the logic levels driven by the probes with the logic levels of the feedback data during each iteration of the test sequence, and counting the number of differences between the logic levels driven by the probes and the logic levels of the feedback data.

23. The method of claim 19, wherein the probes are driven with a first waveform and the collected feedback data from all iterations of the test sequence forms a second waveform.

24. The method of claim 23, wherein the step of computing includes
calculating the absolute surface area (S) of the waveform,
calculating the length of the absolute surface area (L) of the waveform, and
calculating the distribution of the absolute surface area (D) of the waveform, the code corresponding to the values of S, L and D.

25. A method of generating a signature for an electrical system in operation comprising:
a) sampling a waveform of the electrical system;
b) calculating the absolute surface area (S) of the waveform;
c) calculating the length of the absolute surface area (L) of the waveform;
d) calculating the distribution of the absolute surface area (D) of the waveform;
e) displaying the signature corresponding to the values of S, L and D.

26. A probe for use with an electrical component measuring instrument comprising:
an input node;
a non-linear circuit coupled in series to the input node; and
an output node coupled in series to the non-linear circuit.

27. The probe of claim 26, wherein the non-linear circuit includes serially connected pairs of parallel connected resistors and diodes.

28. The probe of claim 27, wherein the value of each resistor is different.
